(19) United States
(12) Patent Application Publication
(10) Pub. No.: US 2014/0373891 A1
(43) Pub. Date: Dec. 25, 2014

(54) THERMOELECTRIC STRUCTURE, AND THERMOELECTRIC DEVICE AND THERMOELECTRIC APPARATUS INCLUDING THE SAME

(71) Applicants: Samsung Electronics Co., Ltd., Suwon-si (KR); Research & Business Foundation SUNGKYUNKWAN UNIVERSITY, Suwon-si (KR)

(72) Inventors: Kyu-hyoung LEE, Hwaseong-si (KR); Sang-il KIM, Seoul (KR); Sung-woo HWANG, Yongin-si (KR); Sung-wng KIM, Suwon-si (KR); Sang-mock LEE, Yongin-si (KR); Young-hee LEE, Suwon-si (KR)

(21) Appl. No.: 14/306,705

(22) Filed: Jun. 17, 2014

(30) Foreign Application Priority Data
Jun. 24, 2013 (KR) 10-2013-0072717

(51) Int. Cl. H01L 35/32; H01L 35/22; H01L 35/16

(52) U.S. Cl. CPC H01L 35/32; H01L 35/16; H01L 35/22
USPC 136/228

(57) ABSTRACT

A thermoelectric structure includes a graphene layer and a thermoelectric body disposed on the graphene layer, in which the thermoelectric body includes a thermoelectric film including a thermoelectric material, and a quantum dot disposed in the thermoelectric film.

### CROSS-REFERENCE TO RELATED APPLICATIONS

This application claims priority to Korean Patent Application No. 10-2013-0072717, filed on Jun. 24, 2013, and all the benefits accruing therefrom under 35 U.S.C. §119, the content of which in its entirety is herein incorporated by reference.

### BACKGROUND

1. Field

The disclosure relates to a thermoelectric structure, and a thermoelectric device and a thermoelectric apparatus including the thermoelectric structure.

2. Description of the Related Art

Thermoelectric devices are devices using a thermoelectric conversion phenomenon. Here, the thermoelectric conversion refers to energy conversion between thermal energy and electrical energy. A Seebeck effect refers to a phenomenon in which electricity is generated when there is a difference in temperature between opposing ends of a thermoelectric material. On the other hand, a Peltier effect refers to a phenomenon in which a temperature gradient is generated at the opposing ends of the thermoelectric material when a current is applied to the thermoelectric material, and thus the application of decreasing the temperature is possible. Such a thermoelectric conversion phenomenon is a reversible and direct energy conversion phenomenon between heat and electricity, and is a phenomenon occurring by the movement of electrons and/or holes within the thermoelectric material.

When the Seebeck effect is used, heat generated from a car engine or various industrial waste heat may be converted into electrical energy. When the Peltier effect is used, various cooling system not requiring use of a refrigerant may be provided. Recently, as interest in the development of new energy, the recovery of waste energy and the protection of environment increase, interest in thermoelectric devices also increases.

The efficiency of the thermoelectric device is determined by a figure of merit, that is, a ZT coefficient, and a non-dimensional ZT coefficient may be expressed by the following Equation:

$$ZT = \frac{{S}^{2} σ}{k} T . \qquad ( 1 )$$

In Equation 1 above, the ZT coefficient is proportional to a Seebeck coefficient S and an electrical conductivity σ and is inversely proportional to a heat conductivity k. The Seebeck coefficient S denotes a magnitude dV/dT of a voltage that is generated by a variation in unit temperature. The Seebeck coefficient S, the electrical conductivity σ, and the heat conductivity k are not independent variables and are mutually influenced. Thus, it is not easy to form a thermoelectric device having a large ZT coefficient, that is, a thermoelectric device having high efficiency.

In order to increase energy conversion efficiency, thermoelectric materials having high Seebeck coefficient, high electrical conductivity and low heat conductivity are required.

### SUMMARY

Provided are embodiments of a thermoelectric structure having an improved thermoelectric performance with low heat conductivity and high electron conductivity.

Provided are embodiments of a thermoelectric module including the thermoelectric device.

Additional features will be set forth in part in the description which follows and, in part, will be apparent from the description, or may be learned by practice of the presented embodiments.

According to an embodiment of the invention, a thermoelectric structure includes a graphene layer; and a thermoelectric body disposed on the graphene layer, where the thermoelectric body comprises a thermoelectric film and a quantum dot disposed in the thermoelectric film.

In an embodiment, thermoelectric film may include a material selected from bismuth (Bi), antimony (Sb), tellurium (Te), selenium (Se) or a combination thereof.

In an embodiment, the quantum dot may include a material which generates carriers by light.

In an embodiment, the material of the quantum dot may include Si, Cu—In—Ga—Se (“GIGS”), CdTe or a combination thereof.

In an embodiment, the quantum dot may include a material having composition which is equal to or less than 5 volume percent (vol %) based on a material of the thermoelectric film.

In an embodiment, the quantum dot may have a diameter equal to or less than about 300 nanometers (nm).

In an embodiment, the thermoelectric film may further include Ag, Cu, Pb, I, CI, Br or a combination thereof.

In an embodiment, the thermoelectric film may be an epitaxial film, which is epitaxially grown on the graphene layer.

According to another embodiment of the invention, a thermoelectric device includes: a graphene layer; a first thermoelectric body disposed on the graphene layer; and an upper electrode disposed on the first thermoelectric body, where the first thermoelectric body includes a thermoelectric film and a quantum dot disposed in the thermoelectric film.

In an embodiment, the thermoelectric device may further include a second thermoelectric body having a different polarity from the first thermoelectric body, where each of the graphene layer and the upper electrode may be divided into a plurality of portions, and the first thermoelectric body and the second thermoelectric body may be connected to a same portion of the graphene layer or a same portion of the upper electrode.

According to another embodiment of the invention, a thermoelectric apparatus includes a thermoelectric device including: a graphene layer; a first thermoelectric body disposed on the graphene layer; and an upper electrode disposed on the first thermoelectric body, where the first thermoelectric body includes a thermoelectric film and a quantum dot disposed in the thermoelectric film.

### BRIEF DESCRIPTION OF THE DRAWINGS

These and/or other features will become apparent and more readily appreciated from the following description of the embodiments, taken in conjunction with the accompanying drawings, in which:

FIG. 1 is a diagram illustrating an embodiment of a thermoelectric structure, according to the invention;

FIGS. 2A and 2B are diagrams illustrating alterative embodiments of forming the thermoelectric structure illustrated in FIG. 1;

FIG. 3 is a diagram illustrating an embodiment of a thermoelectric device including the thermoelectric structure, according to the invention;

FIG. 4 is a diagram illustrating an alternative embodiment of a thermoelectric device including the thermoelectric structure, according to the invention; and

FIG. 5 is a diagram illustrating another alternative embodiment of a thermoelectric apparatus including the thermoelectric structure, according to the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the invention are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

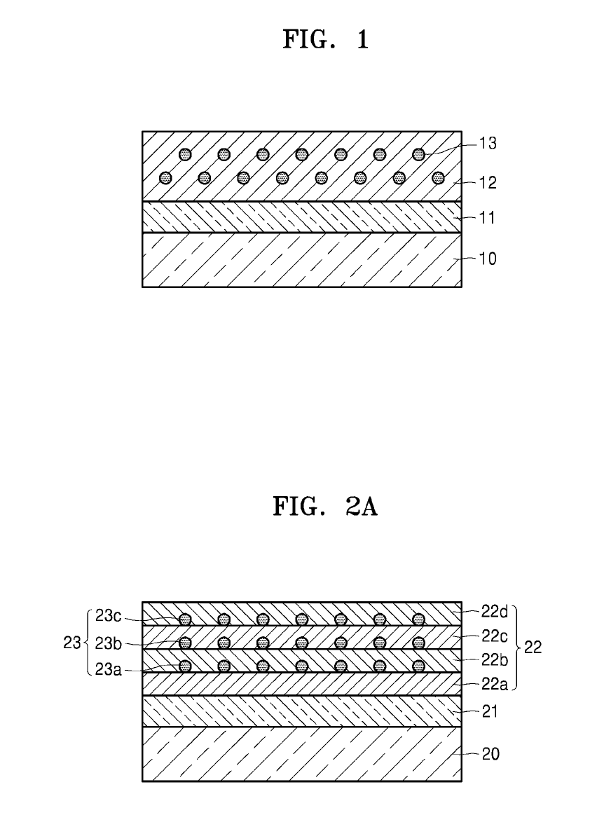

FIG. 1 is a diagram schematically illustrating an embodiment of a thermoelectric structure, according to the invention.

Referring to FIG. 1, the thermoelectric structure may include a graphene layer 11 disposed on a lower structure 10, and thermoelectric bodies 12 and 13 disposed on the graphene layer 11. The thermoelectric bodies 12 and 13 may include a thermoelectric film 12 and a plurality of quantum dots 13. The plurality of quantum dots 13 may be disposed in the thermoelectric film 12.

In such an embodiment of the thermoelectric structure, according to the invention, a thermoelectric-quantum dot complex-type thin film material is disposed on the graphene layer 11. In such an embodiment, a decrease in heat conductivity due to an increase in scattering of phonons at an interface between the graphene layer 11 and the thermoelectric film 12 and an interface between the thermoelectric film 12 and the quantum dot 13 is induced, thereby allowing a phonon glass electron crystal (“PGEC”) behavior to occur therein. In such an embodiment, the generation of carriers due to the quantum dots 13 within the thermoelectric film 12 may be induced to promote the improvement of electrical conductivity. In such an embodiment, a Seebeck coefficient may be increased by forming the quantum dots 13 within the thermoelectric film 12 by a quantum confinement effect. Thus, the figure of merit of the thermoelectric material, as shown in Equation 1 above, may be substantially improved.

The lower structure 10 may include an insulator or a semiconductor material, which may be used as a substrate of a conventional electronic device. In one embodiment, for example, the lower structure 10 may include silicon, silicon oxide, silicon nitride, gallium arsenide (GaAs), sapphire, PYREX®, quartz or a combination thereof.

The graphene layer 11 may be provided, e.g., formed, by various methods. In one embodiment, for example, a catalyst layer including Ni, Cu, Co, Pt or Ru is provided, and then graphene may be provided or formed on the catalyst layer by pyrolysis or chemical vapor deposition (“CVD”) to form the graphene layer 11. Then, the graphene layer 11 form on the catalyst layer may be transferred to a surface of the lower structure 10, and thus the graphene layer 11 disposed on the lower structure may be provided. The graphene layer 11 may have a single layer structure or a multi-layer structure.

The thermoelectric bodies 12 and 13 may be provided by including the quantum dots 13 within the thermoelectric film 12. In such an embodiment, a material for forming the quantum dots 13 may be deposited within the thermoelectric film 12 at the same time when the thermoelectric film 12 is formed. In an embodiment, the thermoelectric bodies 12 and 13 may be provided by repeatedly performing a process of forming a portion of the thermoelectric film 12, forming the quantum dots 13 on the portion of the thermoelectric film 12, and forming the thermoelectric film 12 thereon again. The thermoelectric bodies 12 and 13 may be provided or formed by performing sputtering, CVD, molecular beam epitaxy (“MBE”) or plasma layer deposition (“PLD”), for example, on the graphene layer 11.

A material for forming the thermoelectric film 12 is not particularly limited to a specific material, but includes any material that may be used as a thermoelectric material. In one embodiment, for example, the thermoelectric film 12 may include or be formed of a material having a hexagonal crystal structure, and may include bismuth (Bi), antimony (Sb), tellurium (Te), selenium (Se) or a combination thereof. The thermoelectric film 12 may be epitaxially grown on the graphene layer 11. The thermoelectric film 12 may include or be formed of a p-type or n-type material.

The thermoelectric film 12 may be provided or formed by adding a material such as Ag, Cu, Pb, I, CI, or Br, for example, as additives. The quantum dot 13 may include or be formed of a material having the composition capable of forming carriers by light, and may be formed of a material including, for example, Si, Cu—In—Ga—Se (“GIGS”), or CdTe. A diameter of the quantum dot 13 may be selectively controlled based on a material for providing or forming the thermoelectric film 12. The diameter of the quantum dot 13 may be less than an electron mean free path of the material for forming the thermoelectric film 12, for example, equal to or greater than about zero (0) nanometer (nm) and equal to or less than about 300 nm. The quantum dot 13 may be formed of a material having the composition that is equal to or greater than about zero (0) volume percent (vol %) and equal to or less than about 5 vol % based on the composition of the material for forming the thermoelectric film 12.

Hereinafter, an embodiment of a method of providing a thermoelectric structure including the graphene layer and the thermoelectric body will be described in detail. In such an embodiment, a silicon substrate provided with a silicon oxide film on a surface thereof is prepared as a lower structure. Then, graphene is synthesized on a Cu catalyst layer, and then the resultant product is transferred to a surface of the lower structure, and thus a graphene layer disposed on the lower structure is provided.

An embodiment of a method of synthesizing graphene will now be described in greater detail.

First, Cu foil is put into a furnace, and the temperature is increased up to about 1055° C. for about 40 minutes in a mixed gas atmosphere of hydrogen (H₂) at a flow rate of about 200 standard cubic centimeters per minute (sccm) and argon (Ar) at a flow rate of about 1,000 sccm. Then, this state is maintained for about 60 minutes to achieve flatness of a Cu surface and to reduce a surface oxidation layer. Then, a mixed gas of CH₄ at a flow rate of about 10 sccm, H₂ at a flow rate of about 200 sccm and Ar at a flow rate of about 1,000 sccm is injected thereto for about 3 minutes to synthesize the graphene. Thereafter, the temperature is reduced to a temperature equal to or less than about 100° C. while injecting Ar at a flow rate of about 1,000 sccm for about 40 minutes. As a result, a graphene mono-layer is formed on the Cu foil. The graphene mono-layer formed on the Cu foil is transferred to the silicon substrate, in which the silicon oxide film is formed, and thus the graphene layer is provided on the lower structure.

In an embodiment, a thermoelectric body may be provided or formed on the graphene layer, which is formed by the above-mentioned method, through a PLD process. A Bi₂Te₃ target is prepared to form the thermoelectric film, and an Si target is prepared to form quantum dots, which will hereinafter be described in greater detail.

After oxygen partial pressure of a PLD chamber is maintained at about 5×10⁻⁵ torr, and then an argon gas is injected into the PLD chamber to control the oxygen partial pressure at about 2×10⁻² torr. Then, while the silicon substrate including the silicon oxide film disposed thereon is maintained at about 430° C. by heating, Bi₂Te₃ is deposited for about 1 minute to 5 minutes to form the thermoelectric film, and Si is deposited on the Bi₂Te₃ film to form the quantum dots. After the thermoelectric body including the thermoelectric film and the quantum dots is formed, the substrate is cooled to a temperature equal to or less than about 100° C. The Si quantum dots are deposited with about 1 vol % based on Bi₂Te₃.

When performing an x-ray diffraction pattern (“XRD”) measurement on an embodiment of a thermoelectric structure including the graphene layer and the thermoelectric body which are provided by such a method, only (00n) peak (here, n is a natural number) is observed. Thus, in such an embodiment, the Bi₂Te₃ film is deposited on the graphene layer in an epitaxial state. When measuring heat conductivity in a direction perpendicular to the deposition surface between the Bi₂Te₃ film and the graphene layer, an average value of about 0.63 watts per meter kelvin (W/mK) is measured at room temperature, while an ordinary Bi₂Te₃ bulk material typically has heat conductivity of about 1.0 W/mK. Thus, in such an embodiment, the heat conductivity is decreased by equal to or greater than about 30%. In such an embodiment, when Si quantum dots are provided in the Bi₂Te₃ film with 1 vol %, heat conductivity having an average value of about 0.63 W/mK is measured at the deposition surface between the Bi₂Te₃ film and the graphene layer. In such an embodiment, a decrease in heat conductivity may occur by scattering of phonons or binding of phonons at an interface between the graphene layer and the Bi₂Te₃ film and at an interface between the Si quantum dots and the Bi₂Te₃ film. Accordingly, in such an embodiment, the heat conductivity may be decreased by providing the thermoelectric body containing quantum dots on the graphene layer, and carrier may be generated by the formation of the quantum dots, thereby allowing a thermoelectric performance to be substantially improved.

FIGS. 2A and 2B are diagrams illustrating alternative embodiments of the thermoelectric structure illustrated in FIG. 1.

Referring to FIG. 2A, an embodiment of the thermoelectric structure may include a lower structure 20, a graphene layer 21 disposed on the lower structure 20, and thermoelectric bodies 22 and 23 disposed on the graphene layer 21. The thermoelectric bodies 22 and 23 may include a thermoelectric film 22 and a plurality of quantum dots 23. The thermoelectric bodies 22 and 23 may be configured to have a multi-layered structure in which the plurality of quantum dots 23 is included in the thermoelectric film 22. The multi-layered structure may include quantum dots, e.g., a plurality of first quantum dots 23a, a plurality of second quantum dots 23b and a plurality of third quantum dots 23c, disposed on a plurality layers, e.g., first to fourth layers 22a, 22b, 22c and 22d, defined in the thermoelectric film 22. In one embodiment, as shown in FIG. 2A, the first to third quantum dots 23a, 23b and 23c may be disposed on the first to third layers 22a, 22b and 22c of the thermoelectric film 22, respectively.

Now, a method of forming the thermoelectric bodies 22 and 23 will be described in detail. The first layer 22a of the thermoelectric film 22 is formed, the first quantum dots 23a are provided, e.g., formed, the second thermoelectric film 22b of the thermoelectric film 22 is provided on the first layer 22a of the thermoelectric film 22 and the first quantum dots 23a, and the second quantum dots 23b are provided on the second layer 22b of the thermoelectric film 22. Then, the third layer 22c of the thermoelectric film 22 is provided on the second layer 22b of the thermoelectric film 22 and the second quantum dots 23b, the third quantum dots 23c are provided on the third layer 22c of the thermoelectric film 22, and the fourth layer 22d of the thermoelectric film 22 is disposed. The number of the multi-layers constituting the thermoelectric bodies 22 and 23 is not be limited thereto, and may be variously modified.

FIG. 2B illustrates another alternative embodiment of a thermoelectric structure, in which a plurality of layers, e.g., first to third layers 202a, 202b and 202c, of the thermoelectric film 202, and quantum dots, e.g., first to third quantum dots 203a, 203b and 203c, are simultaneously provided or formed when providing thermoelectric bodies 202 and 203. Referring to FIG. 2B, the thermoelectric structure may include a lower structure 200, a graphene layer 201 disposed on the lower structure 200, and the thermoelectric bodies 202 and 203 disposed on the graphene layer 201. When the thermoelectric bodies 202 and 203 illustrated in FIG. 2B are formed, the layers 202a, 202b, and 202c of the thermoelectric film 202 including corresponding quantum dots 203a, 203b and 203c may be formed by deposition without being separately formed.

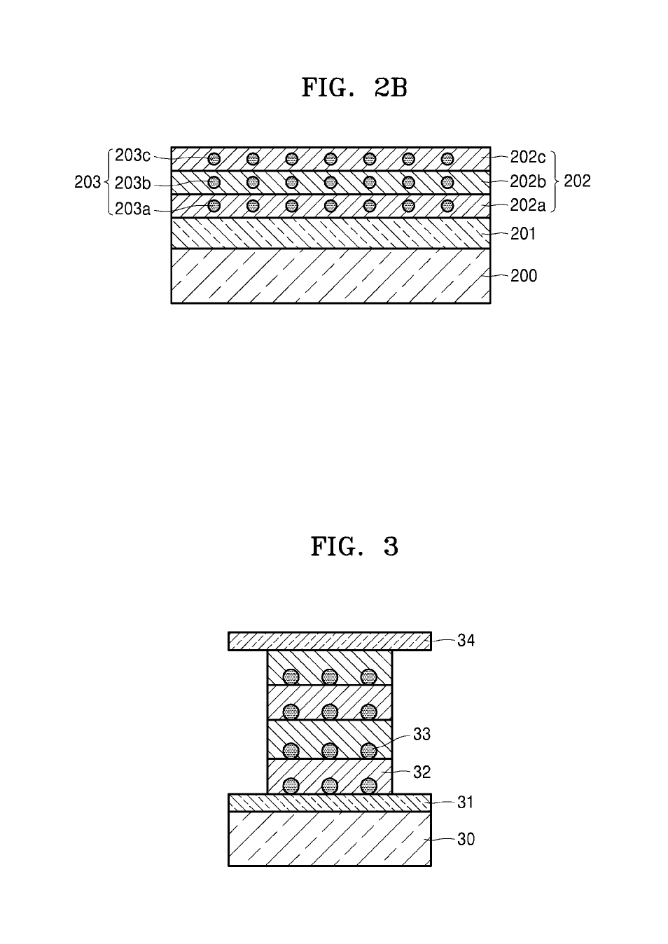

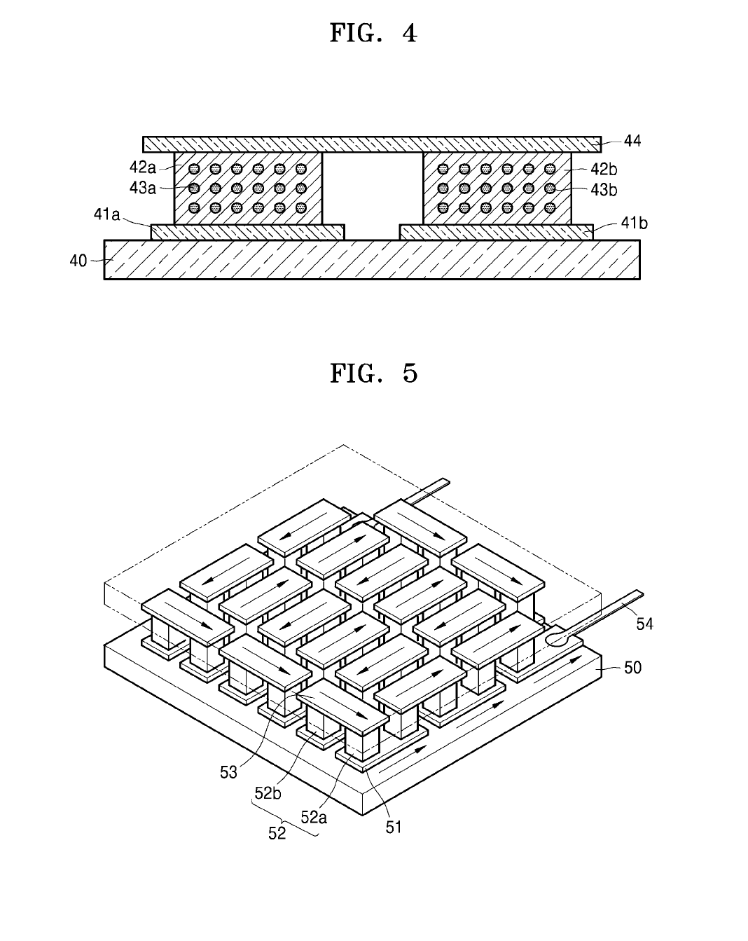

FIGS. 3 and 4 are diagrams illustrating embodiments of a thermoelectric device including a thermoelectric structure, according to the invention.

Referring to FIG. 3, an embodiment of the thermoelectric device may include a lower structure 30, a graphene layer 31 disposed on the lower structure 30, and thermoelectric bodies 32 and 33 disposed on the graphene layer 31, and may further include an upper electrode 34 disposed on the thermoelectric bodies 32 and 33. In such an embodiment, the thermoelectric bodies 32 and 33 may include the thermoelectric film 32, and a plurality of quantum dots 33 disposed in the thermoelectric film 32. Here, the graphene layer 31 may function as a lower electrode. The upper electrode 34 may include or be formed of a metal, a conductive metal oxide, or a conductive metal nitride, for example. Alternatively, the upper electrode 34 may include or be formed of a carbon-containing material. In one embodiment, for example, the upper electrode 34 may include or be formed of graphene. The thermoelectric device has a power generating effect using a difference in temperature between the graphene layer 31 and the upper electrode 34, and thus the thermoelectric device may generate current flowing into the thermoelectric film 32. In such an embodiment, the thermoelectric device may also have a cooling effect based on the application of additional power through the graphene layer 31 and the upper electrode 34.

FIG. 4 is a diagram illustrating an alternative embodiment of a thermoelectric device including a thermoelectric structure, in which first-type thermoelectric bodies 42a and 43a and second-type thermoelectric bodies 42b and 43b are provided as n-type thermoelectric bodies and p-type thermoelectric bodies, respectively. Referring to FIG. 4, an embodiment of the thermoelectric device may include a lower structure 40, a first graphene layer 41a and a second graphene layer 41b which are disposed on the lower structure 40, the first-type thermoelectric bodies 42a and 43a and the second-type thermoelectric bodies 42b and 43b which are respectively disposed on the first graphene layer 41a and the second graphene layer 41b, and an upper electrode 44 disposed on the first-type thermoelectric bodies 42a and 43a and the second-type thermoelectric bodies 42b and 43b. At least one of the first-type thermoelectric bodies 42a and 43a and the second-type thermoelectric bodies 42b and 43b may be substantially the same as the thermoelectric structure described above. Here, the first graphene layer 41a and the second graphene layer 41b may function as a lower electrode. The upper electrode 44 may include or be formed of a metal, a conductive metal oxide, or a conductive metal nitride, for example. Alternatively, the upper electrode 44 may include or be formed of a carbon-containing material. In one embodiment, for example, the upper electrode 44 may include or be formed of graphene. Thus, a thermoelectric module including a plurality of thermoelectric structures may be provided.

FIG. 5 is a diagram illustrating another alternative embodiment of a thermoelectric module, that is, a thermoelectric apparatus, including the thermoelectric structure, according to the invention.

Referring to FIG. 5, an embodiment of the thermoelectric module may include a lower structure 50, a graphene layer 51 divided into a plurality of portions and disposed on the lower structure 50, a plurality of thermoelectric bodies 52 disposed on the graphene layer 51, and an upper electrode 53 divided into a plurality of portions and disposed on the thermoelectric bodies 52. Here, the graphene layer 51 may function as a lower electrode, and the upper electrode 53 may include or be formed of a metal, a conductive metal oxide, or a conductive metal nitride, for example. Alternatively, the upper electrode 53 may include or be formed of a carbon-containing material. In one embodiment, for example, the upper electrode 53 may include or be formed of graphene. In such an embodiment, an upper structure including an insulating material may be further disposed on the upper electrode 53 as illustrated by dotted lines in FIG. 5. In one embodiment, for example, the portions of the graphene layer 51 and the upper electrode 53 may be provided by providing a single graphene layer and a single upper electrode layer and then by patterning the single graphene layer and the single upper electrode layer. In such an embodiment, a first-type thermoelectric body 52a and a second-type thermoelectric body 52b are provided on a portion of the patterned graphene layer 51 or below a portion of the patterned upper electrode 53. In such an embodiment, the first-type thermoelectric body 52a and the second-type thermoelectric body 52b may have opposite polarities to each other. When the first-type thermoelectric body 52a is an n-type thermoelectric body, the second-type thermoelectric body 52b may be a p-type thermoelectric body, or vice versa. The first-type thermoelectric body 52a and the second-type thermoelectric body 52b may share a portion of the graphene layer 51 or a portion of the upper electrode 53, that is connected to a same portion of the graphene layer 51 or a same portion of the upper electrode 53, and may be alternately arranged. At least one of the first-type thermoelectric body 52a and the second-type thermoelectric body 52b may include the thermoelectric structure substantially the same as an embodiment of the thermoelectric structure described above.

Such a thermoelectric apparatus may be connected to the outside through a lead electrode 54 connected to the graphene layer 51 or the upper electrode 53. The thermoelectric apparatus may be connected to an electric apparatus that consumes or stores power through the lead electrode 54 when an electric current (shown as arrows in FIG. 5) is generated therein.

The thermoelectric apparatus illustrated in FIG. 5 may be a thermoelectric generator, a thermoelectric cooler or a thermoelectric sensor, but is not limited thereto. The thermoelectric apparatus may be any apparatus that may perform direct conversion between heat and electricity.

As described above, according to embodiments of the invention, a thermoelectric structure having an improved thermoelectric performance by simultaneously providing low heat conductivity and high electron conductivity, and a thermoelectric device including the thermoelectric structure may be provided.

It should be understood that the embodiments described therein should be considered in a descriptive sense only and not for purposes of limitation. Descriptions of features or aspects within each embodiment should typically be considered as available for other similar features or aspects in other embodiments.

What is claimed is:

1. A thermoelectric structure comprising:
a graphene layer; and
a thermoelectric body disposed on the graphene layer,
wherein the thermoelectric body comprises:
a thermoelectric film; and
a quantum dot disposed in the thermoelectric film.

2. The thermoelectric structure of claim 1, wherein the thermoelectric film comprises bismuth (Bi), antimony (Sb), tellurium (Te), selenium (Se) or a combination thereof.

3. The thermoelectric structure of claim 1, wherein the quantum dot comprises a material which generates carriers by light.

4. The thermoelectric structure of claim 3, wherein the material of the quantum dot comprises Si, Cu—In—Ga—Se, CdTe or a combination thereof.

5. The thermoelectric structure of claim 1, wherein the quantum dot comprises a material having composition equal to or less than about 5 volume percent based on a material of the thermoelectric film.

6. The thermoelectric structure of claim 1, wherein the quantum dot has a diameter equal to or less than about 300 nanometers.

7. The thermoelectric structure of claim 2, wherein the thermoelectric film further comprises Ag, Cu, Pb, I, CI, Br or a combination thereof.

8. The thermoelectric structure of claim 1, wherein the thermoelectric film is an epitaxial film, which is epitaxially grown on the graphene layer.

9. A thermoelectric device comprising:
a graphene layer;
a first thermoelectric body disposed on the graphene layer; and
an upper electrode disposed on the first thermoelectric body,
wherein the first thermoelectric body comprises:
a thermoelectric film; and
a quantum dot disposed in the thermoelectric film.

10. The thermoelectric device of claim 9, wherein the thermoelectric film comprises bismuth (Bi), antimony (Sb), tellurium (Te), selenium (Se) or a combination thereof.

11. The thermoelectric device of claim 9, wherein the quantum dot comprises Si, Cu—In—Ga—Se, CdTe or a combination thereof.

12. The thermoelectric device of claim 9, wherein the quantum dot comprises a material having composition which is equal to or less than about 5 volume percent based on a material of the thermoelectric film.

13. The thermoelectric device of claim 9, wherein the quantum dot has a diameter equal to or less than about 300 nanometers.

14. The thermoelectric device of claim 9, further comprising:
a second thermoelectric body having a different polarity from the first thermoelectric body,
wherein each of the graphene layer and the upper electrode are divided into a plurality of portions, and
the first thermoelectric body and the second thermoelectric body are connected to a same portion of the graphene layer or a same portion of the upper electrode.

15. A thermoelectric apparatus comprising:
a thermoelectric device comprising:
a graphene layer;
a first thermoelectric body disposed on the graphene layer; and
an upper electrode disposed on the first thermoelectric body,
wherein the first thermoelectric body comprises:
a thermoelectric film; and
a quantum dot disposed in the thermoelectric film.

16. The thermoelectric apparatus of claim 15, wherein the thermoelectric film comprises bismuth (Bi), antimony (Sb), tellurium (Te), selenium (Se) or a combination thereof.

17. The thermoelectric apparatus of claim 15, wherein the quantum dot comprises Si, Cu—In—Ga—Se, CdTe or a combination thereof.

18. The thermoelectric apparatus of claim 15, wherein the quantum dot comprises a material having composition which is equal to or less than about 5 volume percent based on a material of the thermoelectric film.

19. The thermoelectric apparatus of claim 15, wherein the quantum dot has a diameter equal to or less than about 300 nanometers.

20. The thermoelectric apparatus of claim 15, wherein the thermoelectric device further comprises:
a second thermoelectric body having a different polarity from the first thermoelectric body,
wherein each of the graphene layer and the upper electrode are divided into a plurality of portions, and
the first thermoelectric body and the second thermoelectric body are connected to a same portion of the graphene layer or a same portion of the upper electrode.
